(19) United States
(12) Patent Application Publication
(10) Pub. No.: US 2003/0042399 A1
(43) Pub. Date: Mar. 6, 2003

(54) Calibration method of an image-capture apparatus

(75) Inventor: Chui-Kuei Chiu, Hsin-Chu (TW)

Correspondence Address: Benjamin J. Hauptman, LOWE HAUPTMAN GILMAN & BERNER, LLP, Suite 310, 1700 Diagonal Road, Alexandria, VA, 22314, US

(73) Assignee: UMAX DATA SYSTEMS INC.

(21) Appl. No.: 09/883,195

(22) Filed: Jun. 19, 2001

(51) Int. Cl. H01L 27/00

(52) U.S. Cl. 250/208.1

(57) ABSTRACT

The present invention provides a calibration method used in an image-capture apparatus. The method comprises providing a calibration chart not built in the image-capture apparatus. Users can select any kind of calibration chart by themselves. The calibration chart consists of pixels arranged in a two-dimensional array, which can prevent dark lines on the output of a scanned article. The information of the calibration chart is captured by the image-capture apparatus and then subjected to a correction means, such as a low-pass filter, whereby corrects aberrance of the information.

### BACKGROUND OF THE INVENTION

1. Field of the Invention

The invention relates to a calibration method for an image-capture apparatus, and more particularly to a calibration method for a scanner.

2. Description of the Prior Art

Scanners for scanning documents, transparent slides and other images are now well known and widely used for various purposes, with the market therefor now being large and steadily increasing. One common type of scanner utilizes one or more linear sensor arrays together with associated lighting and optics to view a single line of an article at a time. An image may be scanned line by line to provide two-dimensional image data, whereby the linear sensor array is moved relative to the article in a direction orthogonal to the length of the linear sensor array at a uniform speed.

In such a scanner, substantial variations in sensitivity are exhibited by the output signals of the various sensor elements along the linear sensor array. These variations result partially from the linear sensor array itself and partially are caused by uneven lighting, dirt on mirrors and other components in the optical system, etc.

Thus, it is common to take one-dimensional background readings of the linear sensors with a built-in calibration base without an article in scanning position to measure these characteristics immediately before a scan. The one-dimensional background outputs are used as a group of one-dimensional calibration values. With scanning an article, the calibration values will normalize the apparent sensitivity of the linear sensor array (or arrays).

However in practice, there are various errors in the one-dimensional calibration values diminishing the performance of the image output. For example, an unexpected value in the one-dimensional calibration values may be due to failure in any a sensor element or an unexpected spot on the built-in calibration chart. The unexpected value may cause dark or light lines along with the image output that is built by scanning an article line by line. Thus, it is important for a scanner to get correct and flexible calibration values.

### SUMMARY OF THE INVENTION

It is an object of the present invention to provide a calibration method for an image-capture apparatus. A calibration chart used in the image-capture apparatus is assignable by a user rather than built in the image-capture apparatus.

It is another object of the present invention to provide a calibration method for a scanner. The information of calibration chart can be automatically corrected for preventing misreading caused by exterior factors, such as dusts.

It is yet an object of the present invention to provide a calibration method for a scanner. The calibration method can prevent a scanned article from dark or light lines along with the image output of the scanned article.

In the present invention, a calibration method used in an image-capture apparatus comprises providing a calibration chart not built in the image-capture apparatus. Users can select any kind of calibration chart by themselves. The calibration chart consists of pixels arranged in a two-dimensional array, which can prevent dark lines on the output of a scanned article. The information of the calibration chart is captured by the image-capture apparatus and then subjected to a correction means, such as a low-pass filter, whereby corrects aberrance of the information.

### BRIEF DESCRIPTION OF THE DRAWINGS

A better understanding of the invention may be derived by reading the following detailed description with reference to the accompanying drawing wherein:

FIG. 1 is a flow chart of calibration values in accordance with the present invention;

FIG.2 is a schematic diagram illustrating the calibration image combined with the objective image of a scanned article in accordance with the present invention; and

FIG. 3 is a schematic diagram illustrating the calibration charts used in a scanner in accordance with the present invention.

### DESCRIPTION OF THE PREFERRED EMBODIMENT

The calibration method of the present invention is applicable to a board range of image-capture apparatus and various objective articles. While the invention is described in terms of a single preferred embodiment, those skilled in the art will recognize that many steps described below can be altered without departing from the spirit and scope of the invention.

Furthermore, shown is a representative portion of the calibration of the present invention. The drawings are not necessarily to scale for clarity of illustration and should not be interpreted in a limiting sense. Accordingly, these articles may have dimensions, including length, width and depth, when scanned in an actual apparatus.

In the present invention, a calibration method of improving an output performance of an article captured by a scanner comprises providing a calibration chart wherein consists of a portion of pixels aligned in a direction and another portion of the pixels aligned orthogonal to the direction. The calibration chart is scanned for capturing information of all the pixels and then the information of all the pixels is subjected to a correction means whereby corrects aberration of the partial pixels.

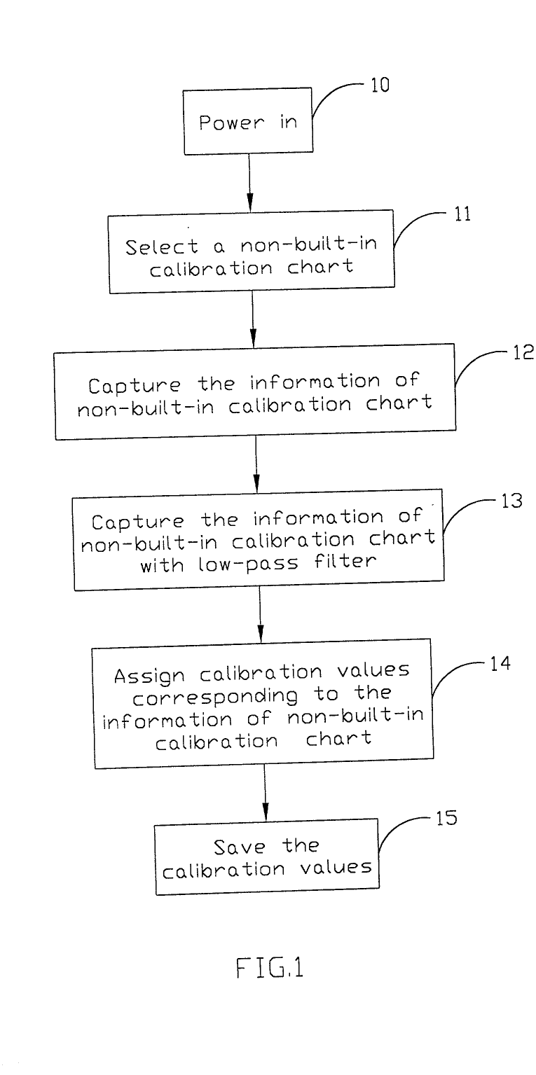

FIG. 1 is a schematic flow chart illustrating a series of steps in accordance with the present invention. An image-capture apparatus, such as a scanner, is first power-on (step 10). For calibration process of the present invention, users can select a non-built-in calibration chart (step 11). One of advantages of using a non-built-in calibration chart is to save the volume of the scanner. Another advantage of using the non-built-in calibration chart is to enable the scanner to scan diverse articles by changing any suitable calibration chart. Using changeable calibration chart can prevent the scanned article from having pixels of brightness saturation that are compared with unsuitable calibration values.

Furthermore, different from any conventional calibration chart built in a general scanner and restricted on linear one-dimensional chart for the linear sensor array, the non-built-in calibration chart can have no restriction on the dimensions. That is, the non-built-in calibration chart may have pixels in the two dimensions (parallel to the length of the linear sensor array and orthogonal thereto), even as well as the size of a whole scanned zone. One of advantages of using a two-dimensional calibration chart is to prevent from dark lines resulted from misreading or any aberrant condition during capturing the information of the calibration chart.

Furthermore, the non-built-in calibration chart may be white, black, or have a homogeneous gray hue thereon. Users can select or change the non-built-in calibration charts with various homogenous gray hues to fit in with various objective articles. Such a calibration chart can prevent the scanned image of an objective article from forming saturated pixels thereon. The saturated pixels on the scanned image result from multitudes of signal values corresponding the objective article beyond the value range of conventional calibration chart. The quality of the scanned image may be deteriorated because of the existence of saturated pixels. One of advantages of the present invention provides users selecting suitable calibration chart prior to scanning the objective article, and further improves the quality of the scanned image.

Next, the information of the non-built-in calibration chart is captured by the scanner (step 12). After analog/digital transformation, the signal values corresponding to the non-built-in calibration chart are primarily subjected to a low-pass filter (step 13). When the size of the calibration chart is enlarged, the probability of aberrant pixels on the calibration chart increases. In the present invention, the low-pass filter can normalize the signal values corresponding to the aberrant pixels of the calibration chart and further reduce the influence of the aberrant pixels.

Next, users can check the output values of the calibration chart with a host computer. In the present invention, users can not only view the output values of the calibration chart, but also assign the desired output values of the calibration chart by themselves (step 14). In the present invention, the assignable output values corresponding to the calibration chart provides flexibly operable capability on scanning the objective article. Furthermore, users can save the assigned output values corresponding to the calibration chart (step 15).

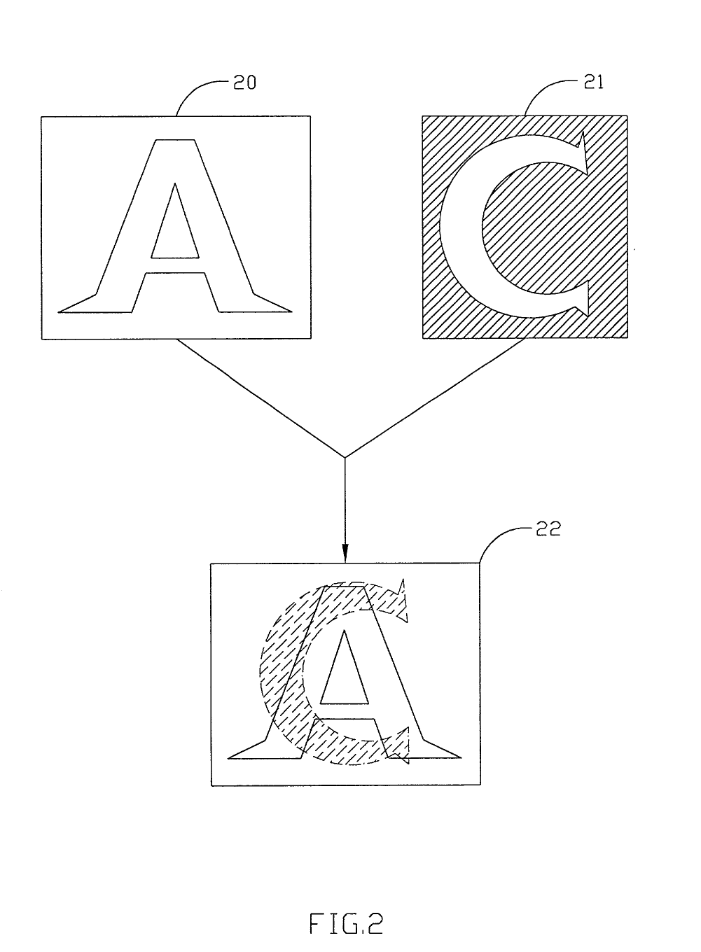

FIG. 2 is a schematic diagram illustrating the non-built-in calibration chart having a pattern in accordance with the present invention. A desired calibration chart 21 has a pattern “C” that may have a hue different from the background of the desired calibration chart 21. The desired calibration chart 21 is captured by the scanner and the output values thereof are saved as the calibration values for the scanner. Then an objective article 20 is scanned for getting the output image of the objective article 20. In the embodiment, the output image of the objective article 20 can be combined with the desired calibration chart 21 to output a background-output image 22. The pattern “C” on the desired calibration chart 21 is used as a watermark for the objective article 20. In the background-output image 22, the pattern “C” may have a lighter or darker hue than the pattern on the desired calibration chart 21. Furthermore, the original pattern of the objective article 20 overlapped the pattern of the desired calibration chart 21 may have a different hue from one of the objective article 20. Thus, the desired calibration chart 21 provides not only the calibration values for the scanner, but also is used as background values for the objective article 20.

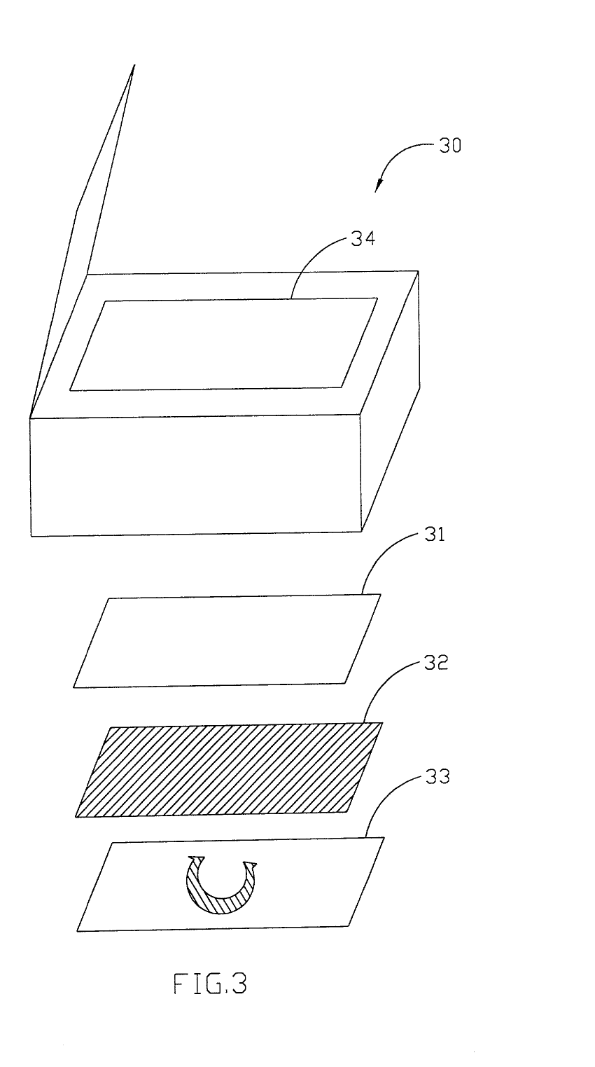

FIG. 3 illustrates the calibration charts used in a scanner in accordance with the present invention. A scanning platform 34 for putting any scanned article is provided on a reflective or penetrant scanner 30. In the present invention, a white (or black) chart 31, a hued chart 32, or a chart with a word “C” 33, may be used as a calibration chart and have a dimension as large as the scanning platform 34 has. Thus, the scanner 30 of the present invention can capture whole information of the calibration chart as calibration data for the scanner 30.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A calibration method used in an image-capture apparatus, said method comprising:
providing a calibration chart not built in said image-capture apparatus;
capturing a plurality of information of said calibration chart by said image-capture apparatus; and
subjecting said information of said calibration chart to a correction means whereby corrects aberrance of said information.

2. The method according to claim 1 further comprising:
assigning a plurality of corresponding calibration values to said information with a host computer; and
storing said corresponding calibration values for utilization of said image-capture apparatus.

3. The method according to claim 1, wherein said image-capture apparatus comprises a plurality of sensor elements aligned in a direction.

4. The method according to claim 3, wherein said calibration chart comprises a portion of a plurality of pixels aligned in said direction and another portion of said pixels aligned orthogonal to said direction.

5. The method according to claim 4, wherein all said pixels are with a homogenous hue.

6. The method according to claim 4, wherein all said pixels are with different hues, whereby are outputted combined with an object article.

7. The method according to claim 1, wherein said correction means comprises a low-pass filter.

8. A calibration method of improving an output performance of an article captured by a scanner, said method comprising:
providing a calibration chart wherein consists of a portion of a plurality of pixels aligned in a direction and another portion of said pixels aligned orthogonal to said direction;
scanning said calibration chart for capturing a plurality of information of all said pixels; and
subjecting said information of all said pixels to a correction means whereby corrects aberration of partial said pixels.

9. The method according to claim 8, wherein said calibration chart comprises being not built in said scanner.

10. The method according to claim 8, wherein all said pixels are with a homogenous hue.

11. The method according to claim 8, wherein all said pixels are with different hues, whereby are outputted combined with said article.

12. The method according to claim 8, wherein said correction means comprises a low-pass filter.

13. The method according to claim 8, wherein said scanning step comprises scanning said calibration chart with a linear sensor array of said scanner wherein consists of a plurality of sensor elements aligned in said direction.

14. A method of capturing calibration information used in a scanner, said method comprising:
providing a calibration chart consisting of a plurality of pixels arranged in a two-dimensional array; and
scanning all said pixels with a linear sensor array in said scanner, said linear sensor array consisting of sensor elements aligned in a direction and moving orthogonal to said direction for building said calibration information of said calibration chart.

15. The method according to claim 14 further comprising subjecting said calibration information to a low-pass filter whereby corrects aberration of partial said pixels.

16. The method according to claim 14 further comprising assigning a plurality of calibration values to said calibration information with a computer connected with said scanner.

17. The method according to claim 14, wherein all said pixels comprise being with a homogenous hue.

18. The method according to claim 14, wherein all said pixels comprise being with different hues, whereby are outputted combined with a scanned article.
